(19) United States
(12) Patent Application Publication
(10) Pub. No.: US 2024/0224624 A1
(43) Pub. Date: Jul. 4, 2024

(54) Organic Light Emitting Display Device

(71) Applicant: LG Display Co., Ltd., Seoul (KR)

(72) Inventors: Soobin Lee, Seoul (KR); Se Yong Lee, Paju-si (KR)

(21) Appl. No.: 18/511,734

(22) Filed: Nov. 16, 2023

(30) Foreign Application Priority Data
Dec. 29, 2022 (KR) 10-2022-0188757

(51) Int. Cl. H10K 59/124; H10K 59/80

(52) U.S. Cl. CPC H10K 59/124; H10K 59/80515

(57) ABSTRACT

An organic light emitting display device is disclosed. This organic light emitting display device, comprises an insulating layer disposed on a substrate, an organic light emitting diode disposed on the insulating layer and including a first electrode, an emission layer, and a second electrode, wherein the insulating layer includes a convex portion disposed in a curved area protruding forward, wherein the emission layer is disposed in an emission area, and the emission area is included in the curved area as at least a part of the curve area, wherein the organic light emitting diode is disposed on the convex portion to have a shape corresponding to a surface shape of the convex portion in the emission area.

### CROSS-REFERENCE TO RELATED APPLICATION

This application claims the benefit of and priority to Republic of Korea Patent Application No. 10-2022-0188757 filed on Dec. 29, 2022, in the Republic of Korea, which is incorporated by reference in its entirety.

### BACKGROUND

### Technical Field

The present disclosure relates to an organic light emitting display device, and more particularly, to an organic light emitting display device in which a convex portion for adjusting a light path is disposed.

### Discussion of the Related Art

Demand for display devices for displaying images is increasing in various forms in accordance with gradual technological development. Recently, various display devices such as liquid crystal displays (LCDs), plasma display panels (PDPs), and organic light emitting diode (OLED) display devices are being utilized. Such display devices are applied to various fields of application such as TVs (televisions), automobile displays, wearable devices and the like as well as mobile devices, for example, smart phones and tablet personal computers (PCs). Structural variations of display devices are required so that the display devices are applied to various fields of application. Meanwhile, display devices output light through a precisely designed light path to exhibit constant luminance and colors in a direction in which a user looks. However, if the direction in which the user looks and the light path do not coincide with each other, since image expression is different for each area of the display device, it is necessary to design the light path appropriately according to use environments and a detailed structure of the display device.

### SUMMARY

An aspect of the present disclosure is to provide a display device capable of preventing or at least reducing degradation in visibility due to an increase in an area of the display device or a flexible deformation of a part of the display device.

Objects of the present disclosure are not limited to the above-mentioned objects, and other objects, which are not mentioned above, can be clearly understood by those skilled in the art from the following descriptions.

According to an aspect of the present disclosure, there is provided an organic light emitting display device. This organic light emitting display device, comprises an insulating layer disposed on a substrate, an organic light emitting diode disposed on the insulating layer and including a first electrode, an emission layer, and a second electrode, wherein the insulating layer includes a convex portion disposed in a curved area protruding forward, wherein the emission layer is disposed in an emission area, and the emission area is included in the curved area as at least a part of the curve area, wherein the organic light emitting diode is disposed on the convex portion to have a shape corresponding to a surface shape of the convex portion in the emission area.

Other detailed matters of the exemplary embodiments are included in the detailed description and the drawings.

According to the present disclosure, even when viewing a display device from a side thereof, it is possible to provide a user with excellent visibility without a change in luminance or colors.

According to the present disclosure, an image in a bending area and an image in an area other than the bending area can be constantly and uniformly transmitted to a user looking at a display device in a front thereof, without a difference in luminance and color.

According to the present disclosure, an image can be provided to a user looking a large display device in a front thereof, without variations in luminance and colors.

According to the present disclosure, a difference in luminance and color distortion between various colors expressed through light emitting elements can be corrected.

According to the present disclosure, luminance and colors distorted due to a protective layer disposed over a display panel can be corrected.

The effects according to the present disclosure are not limited to the contents exemplified above, and more various effects are included in the present specification.

### BRIEF DESCRIPTION OF THE DRAWINGS

FIG. 1 is a perspective view illustrating a display device according to an exemplary embodiment of the present disclosure.

FIG. 2 is a view illustrating display devices according to exemplary embodiments of the present disclosure.

FIG. 3 is a schematic plan view of a display device according to another exemplary embodiment of the present disclosure.

FIG. 4 is a schematic plan view of a display device according to still another exemplary embodiment of the present disclosure.

FIG. 5 is a cross-sectional view of a display device according to still another exemplary embodiment of the present disclosure.

FIG. 6 is a cross-sectional view illustrating a stacked structure of an organic light emitting diode disposed in the display device according to an exemplary embodiment of the present disclosure.

FIG. 7 is a schematic plan view of a display device according to still another exemplary embodiment of the present disclosure.

FIG. 8 is a cross-sectional view illustrating a stacked structure of an organic light emitting diode disposed in the display device according to still another exemplary embodiment of the present disclosure.

FIG. 9 is a schematic cross-sectional view of a display device including a protective layer according to still another exemplary embodiment of the present disclosure.

FIG. 10 is a cross-sectional view illustrating a stacked structure of an organic light emitting diode disposed in the display device of FIG. 9 according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

When description is made with ‘connected’ or ‘coupled’, it may include being ‘connected’ or ‘coupled’ through one or more other components positioned between two components unless ‘immediately’ or ‘directly’ is used.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an organic light emitting display device according to exemplary embodiments of the present disclosure will be described in detail with reference to accompanying drawings.

Transistors used in display devices according to exemplary embodiments of the present disclosure may be implemented as one of n-channel transistors (NMOS) and p-channel transistors (PMOS). The transistor may be implemented as an oxide semiconductor transistor having an oxide semiconductor as an active layer or a low temperature poly-silicon (LTPS) transistor having LTPS as an active layer. The transistor may include at least a gate electrode, a source electrode, and a drain electrode. The transistor may be implemented as a thin film transistor (TFT) on a display panel. In the transistor, carriers flow from the source electrode to the drain electrode. In the case of the n-channel transistor (NMOS), since carriers are electrons, a source voltage may have a voltage level lower than that of a drain voltage so that the electrons may flow from the source electrode to the drain electrode. In the n-channel transistor (NMOS), current flows in a direction from the drain electrode to the source electrode, and the source electrode may be an output terminal. In the case of the p-channel transistor (PMOS), since carriers are holes, a source voltage may have a voltage level higher than that of a drain voltage so that the holes may flow from the source electrode to the drain electrode. In the p-channel transistor PMOS, since the holes flow from the source electrode to the drain electrode, current flows from a source to a drain of the transistor, and the drain electrode may be an output terminal. Accordingly, it should be noted that the source and drain of the transistor are not fixed because the source and drain may change according to a voltage applied thereto. In the disclosure, description is made assuming that the transistor is an n-channel transistor (NMOS), but it is not limited thereto, and a p-channel transistor may be used therefor and accordingly, a circuit configuration may be changed.

A gate signal of the transistors used as switching elements may swing between a gate-on voltage and a gate-off voltage. The gate-on voltage may be set to a voltage higher than a threshold voltage Vth of the transistor, and the gate-off voltage may be set to a voltage lower than the threshold voltage Vth of the transistor. The transistor may be turned on in response to the gate-on voltage, while being turned off in response to the gate-off voltage. In the case of the n-channel transistor (NMOS), the gate-on voltage may be a gate high voltage (VGH), and the gate-off voltage may be a gate low voltage (VGL). In the case of the p-channel transistor (PMOS), the gate-on voltage may be the gate low voltage (VGL), and the gate-off voltage may be the gate high voltage (VGH).

Hereinafter, various exemplary embodiments of the present disclosure will be described in detail with reference to the accompanying drawings.

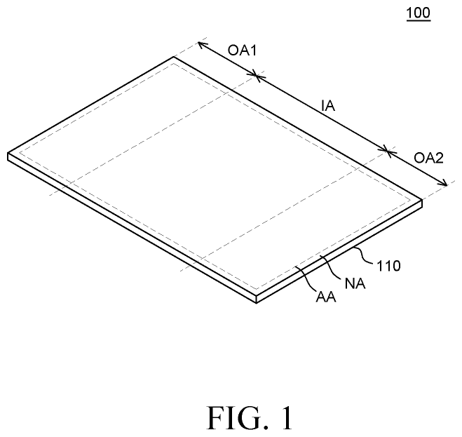

FIG. 1 is a perspective view illustrating a display device according to an exemplary embodiment of the present disclosure.

Referring to FIG. 1, a display device 100 may include an inner area IA and a plurality of outer areas OA1 and OA2 disposed outside the inner area IA. In FIG. 1, the outer areas OA1 and OA2 are illustrated as being disposed on both side surfaces of the inner area IA, but the present disclosure is not limited thereto. The outer areas OA1 and OA2 may surround all surfaces of the inner area IA. The inner area IA may be formed of a non-flexible substrate, and the outer areas OA1 and OA2 may be formed of a flexible or non-flexible substrate. Accordingly, the outer areas OA1 and OA2 may be referred to as bending areas.

Meanwhile, the display device 100 may include an active area AA and a non-active area NA. The active area AA is an area in which an image is displayed, and the non-active area NA is an area in which an image is not displayed. Driving units or lines for driving the active area AA may be disposed in the non-active area NA. The non-active area NA may surround an edge of the active area AA.

In the display device 100, the active area AA may be disposed in the outer areas OA1 and OA2 and the inner area IA. Accordingly, the display device 100 which is flexible may display an image through the outer areas OA1 and OA2 and the inner area IA.

The display device 100 includes a display panel 110 that displays an image, and the display panel 110 may be formed as various types of display panel such as an organic light emitting diode (OLED) panel and a liquid crystal display (LCD) panel. In the disclosure, description is made assuming that the display panel 110 of the display device 100 according to various exemplary embodiments of the present disclosure is an OLED panel.

Meanwhile, although not illustrated, the display panel 110 may include a plurality of data lines and a plurality of gate lines, and may include a plurality of sub-pixels defined by the plurality of data lines and the plurality of gate lines. Further, each sub-pixel may include circuit elements such as an organic light emitting diode (OLED) and a driving transistor for driving the organic light emitting diode (OLED).

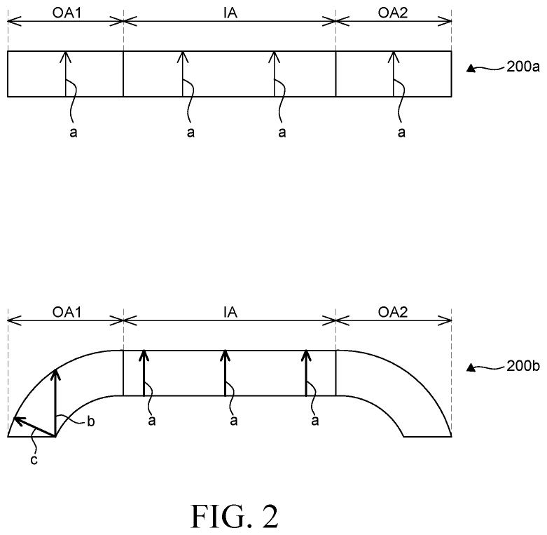

FIG. 2 is a view illustrating display devices according to exemplary embodiments of the present disclosure. Specifically, FIG. 2 illustrates a non-flexible display device and a flexible display device.

Referring to FIG. 2, a non-flexible display device 200a is a display device including a non-bending area. For example, the non-flexible display device 200a may not be bent in the inner area IA and the outer areas OA1 and OA2. The non-flexible display device 200a may be configured as a flat panel display device, but is not limited thereto and may be implemented in a partially bent form.

A flexible display device 200b is a display device including a bending area and a non-bending area. For example, in the flexible display device 200b, a non-flexible substrate may be disposed in the inner area IA, and a flexible substrate may be disposed in at least one of the outer areas OA1 and OA2. Accordingly, the inner area IA may maintain a planar shape without being bent. On the other hand, the outer areas OA1 and OA2 may be bent and have a curved shape. Meanwhile, in FIG. 2, the outer areas OA1 and OA2 disposed on both sides of the inner area IA are illustrated as bending areas, but a position of the bending area is not limited thereto. For example, only one of the outer areas OA1 and OA2 may be bent, and the other may not be bent.

Meanwhile, in the inner area IA and the outer areas OA1 and OA2 of the non-flexible display device 200a, a majority of light emitted from the organic light emitting diode comes out in a front direction of the display device, so that a user looking at the display device from a front thereof can see an image with high visibility. However, when the user looks at the display device from a side thereof, the light is not diffused toward the user, which may cause defects such as a decrease in luminance and color coordinate distortion.

Also, in the case of the flexible display device 200b compared to the non-flexible display device 200a, light paths may be different in the outer areas OA1 and OA2. Specifically, when the user looks at the display device in the front thereof, differences in the impression of a color and luminance between the inner area IA and the outer areas OA1 and OA2 are caused since the amount of light c exiting in a lateral direction of the display device from the outer areas OA1 and OA2 is greater than the amount of light b exiting in the front direction of the display device from the outer areas OA1 and OA2. Accordingly, the user looking at the display device may see an image with degraded visibility.

As described above, when the non-flexible display device 200a is enlarged or the flexible display device 200b is used, there is a limitation in that visibility is degraded due to a problem in optical paths. According to various exemplary embodiments of the present disclosure, even when a user looks the display device from the side thereof or bends a part of the display device, the user can watch an image with excellent visibility. Hereinafter, a structure of a display device for improving visibility will be described in detail.

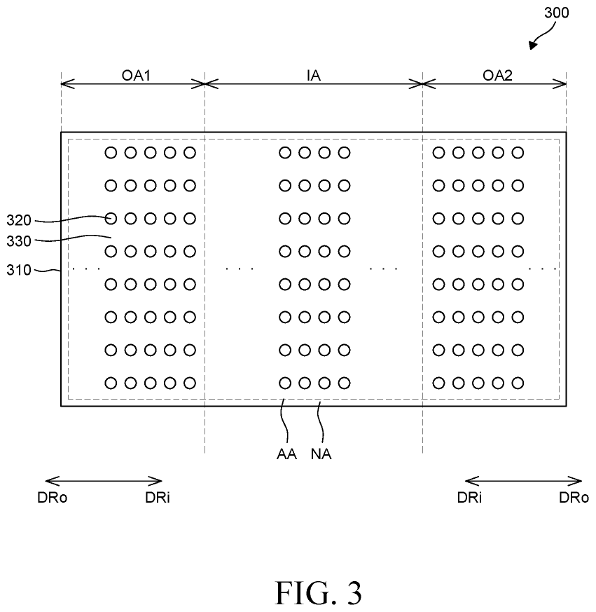

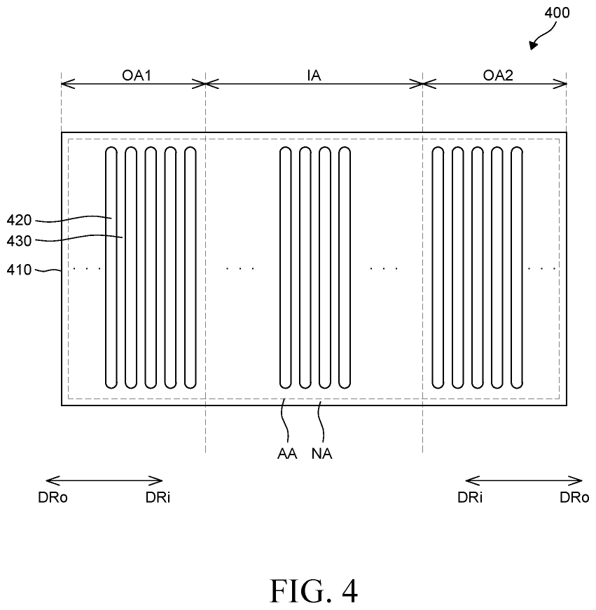

FIG. 3 is a schematic plan view of a display device according to another exemplary embodiment of the present disclosure. FIG. 4 is a schematic plan view of a display device according to still another exemplary embodiment of the present disclosure.

Referring to FIGS. 3 and 4, display devices 300 and 400 include an active area AA and a non-active area NA, and an inner area IA and outer areas OA1 and OA2 thereof include the active area AA at least partially. The display devices 300 and 400 may display an image in both the inner area IA and the outer areas OA1 and OA2.

The display devices 300 and 400 include insulating layers 310 and 410 disposed on a substrate. The insulating layers 310 and 410 may be disposed on the inner area IA and the outer area OA1 and OA2. For example, the insulating layers 310 and 410 may be disposed in a part or an entirety of the active area AA and the non-active area NA of the inner area IA. In addition, the insulating layers 310 and 410 may be disposed in a part or an entirety of the active area AA and the non-active area NA of the outer areas OA1 and OA2.

The insulating layers 310 and 410 may include a plurality of convex portions 320 and 420 and connection portions 330 and 430.

The plurality of convex portions 320 and 420 may protrude in a direction toward upper surfaces of the insulating layers 310 and 410. For example, the convex portions 320 and 420 may have shapes in which they protrude to form curved surfaces toward fronts of the display device 300 and 400.

Referring to FIG. 3, the plurality of convex portions 320 and 420 may be disposed in the inner area IA and the outer area OA1 and OA2 of the display devices 300 and 400. The convex portions 320 may be disposed in a shape of dots in the inner area IA and the outer areas OA1 and OA2 of the display device 300. Also, referring to FIG. 4, the convex portions 420 may have a line pattern. For example, the convex portions 420 may be disposed in a shape having long axes in a column direction.

The connection portions 330 and 430 are disposed outside the plurality of convex portions 320 and 420 and surround the convex portions 320 and 420. The connection portions 330 and 430 may be integrally formed with the convex portions 320 and 420. For example, the connection portions 330 and 430 may be formed of the same material as the convex portions 320 and 420.

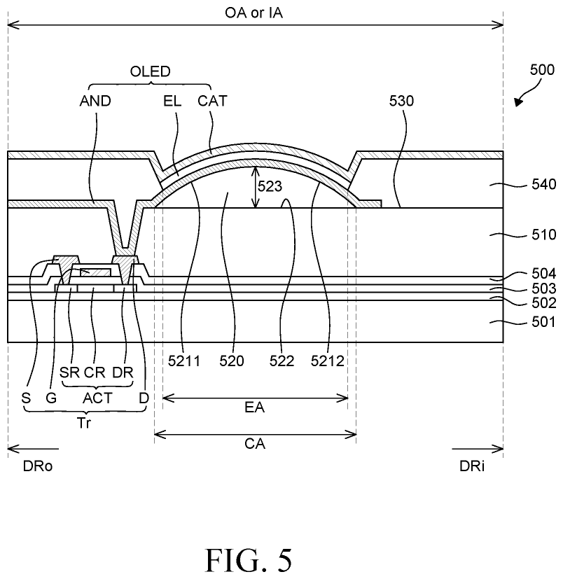

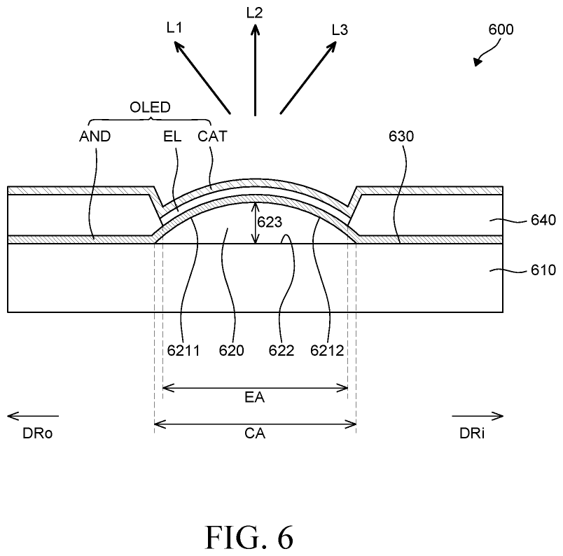

FIG. 5 is a cross-sectional view of a display device according to still another exemplary embodiment of the present disclosure. FIG. 6 is a cross-sectional view of an organic light emitting diode disposed in the display device according to an exemplary embodiment of the present disclosure. FIG. 5 is a cross-sectional view of a convex portion which is described with reference to FIGS. 3 and 4. A stacked structure illustrated in FIG. 6 may be applied to other stacked structures as well as a stacked structure illustrated in a cross-section of FIG. 5, and various exemplary embodiments of the present disclosure are not limited to the stacked structure illustrated in FIG. 5.

Referring to FIGS. 5 and 6, a display device 500 includes at least one transistor Tr disposed on a substrate 501 and an organic light emitting diode OLED electrically connected to the transistor Tr. The transistor Tr includes a semiconductor layer ACT, a gate electrode G, a source electrode S, and a drain electrode D, and the organic light emitting diode OLED includes a first electrode AND, an emission layer EL, and a second electrode CAT.

A buffer layer 502 is disposed on the substrate 501 of the display device 500, the semiconductor layer ACT including a source region SR, a channel region CR, and a drain region DR is formed on the buffer layer 502, and a gate insulating layer 503 is disposed on the semiconductor layer ACT. Here, the semiconductor layer ACT may be an oxide semiconductor layer, but is not limited thereto.

The gate electrode G which is disposed to overlap the channel region CR of the semiconductor layer ACT is disposed on the gate insulating layer 503, and an interlayer insulating layer 504 is disposed on the gate electrode G. The source electrode S connected to the source region SR of the semiconductor layer ACT and the drain electrode D connected to the drain region DR of the semiconductor layer ACT are disposed on the interlayer insulating layer 504.

Insulating layers 510 and 610 are disposed on the source electrode S and the drain electrode D. Here, the insulating layers 510 and 610 may be formed of an organic material and have an effect of flattening the substrate 501. These insulating layers 510 and 610 may also be referred to as a planarization film.

Convex portions 520 and 620 are disposed on the insulating layers 510 and 610. As described with reference to FIGS. 3 and 4, the convex portions 520 and 620 may be disposed in the inner area IA and the outer areas OA1 and OA2, and the plurality of convex portions 520 and 620 are disposed such that adjacent convex portions 520 and 620 are spaced apart from each other. In addition, connection portions 530 and 630 connecting the adjacent convex portions 520 and 620 may be disposed between the convex portions 520 and 620.

The convex portions 520 and 620 are disposed to protrude while forming curves in a front direction of the display device 500.

The convex portions 520 and 620 respectively include outer curved surfaces 5211 and 6211, inner curved surfaces 5212 and 6212, and flat bottom surfaces 522 and 622. The outer curved surfaces 5211 and 6211 are surfaces of the convex portions 520 and 620 located on an outer side (DRo) of the display device 500, and the inner curved surfaces 5212 and 6212 are surfaces of the convex portions 520 and 620 located on an inner side (DRi) of the display device 500. The outer curved surfaces 5211 and 6211 and the inner curved surfaces 5212 and 6212 may be divided based on positions where heights 523 and 623 of the convex portions 520 and 620 are greatest. For example, the heights 523 and 623 of the convex portions 520 and 620 gradually decrease toward the inner side DRi and the outer side DRo of the display device 500. The outer curved surfaces 5211 and 6211 and the inner curved surfaces 5212 and 6212 may be formed symmetrically with respect to each other, but are not limited thereto.

Meanwhile, the convex portions 520 and 620 may be formed of the same material as the insulating layers 510 and 610, but are not limited thereto. The convex portions 520 and 620 may be formed of, for example, polyimide (PI) or polyacrylate (PAC).

The first electrode AND of the organic light emitting diode OLED is disposed on the insulating layers 510 and 610 and the convex portions 520 and 620. The first electrodes AND are flatly disposed on the insulating layers 510 and 610 along upper surfaces of the insulating layers 510 and 610, and are disposed on the convex portions 520 and 620 to form curves which protrude forward along surface shapes of the convex portions 520 and 620.

Banks 540 and 640 are disposed on the first electrodes AND. The banks 540 and 640 may be disposed on portions of front surfaces of the first electrodes AND and the insulating layers 510 and 610 to partially expose the front surfaces of the first electrodes AND. The banks 540 and 640 may define emission areas EA by partially exposing the front surfaces of the first electrodes AND. That is, areas opened by the banks 540 and 640 may be the emission areas EA, and areas overlapping areas where the banks 540 and 640 are located may be non-emission areas (not illustrated).

Meanwhile, at least portions of the banks 540 and 640 may be disposed on the first electrodes AND forming curves by the convex portions 520 and 620. At least portions of the banks 540 and 640 are disposed on the curved first electrodes AND, so that curved areas CA where the convex portions 520 and 620 are formed include the emission areas EA. That is, the emission area EA is smaller than the curve area CA.

The emission layer EL is disposed on the front surfaces of the first electrodes AND exposed by the banks 540 and 640. The emission layers EL may be disposed in areas overlapping the convex portions 520 and 620 to come into contact with the first electrodes AND. Accordingly, the emission layers EL may have shapes corresponding to the convex portions 520 and 620.

The second electrode CAT is disposed on the emission layers EL and the banks 540 and 640. The second electrodes CAT may be disposed on the banks 540 and 640 in a flat shape, and may be disposed in the areas overlapping the convex portions 520 and 620 and have shapes corresponding to the convex portions 520 and 620.

Between the insulating layers 510 and 610 and the first electrodes AND, the convex portions 520 and 620 forming curved surfaces and protruding forward are disposed in the curved areas CA, and the emission layers EL are disposed in the emission areas EA. In addition, the emission area EA is included in the curve area CA as at least a part of the curve area CA, and the organic light emitting diodes OLED may be disposed on the convex portions 520 and 620 to have shapes corresponding to the surface shapes of the convex portions 520 and 620 in the emission areas EA. Furthermore, the emission areas EA are defined by the banks 540 and 640 disposed on the insulating layers 510 and 610 and the first electrodes AND. At least portions of the banks 540 and 640 are disposed on the curved areas CA and accordingly, the emission area EA is included in the curved area CA as at least a part of the curved area CA. The emission layers EL may have shapes corresponding to the surface shapes of the convex portions 520 and 620 overall.

Meanwhile, although not illustrated in the drawings, the emission layer EL may be formed of a plurality of layers including a hole injection layer, a hole transport layer, an organic emission layer, an electron transport layer, and an electron injection layer that are disposed on the first electrode AND. The plurality of layers included in the emission layers EL may have shapes corresponding to the surface shapes of the convex portions 520 and 620 in the emission areas EA.

Referring to FIG. 6, the emission area EA is included in the curve area CA as a part of the curve area CA, and the organic light emitting diode OLED has a curve shape corresponding to the curved shape of the convex portions 520 and 620, so that light emitted from the organic light emitting diode OLED is diffused in a dome shape. For example, as illustrated in FIG. 6, among the light emitted from the organic light emitting diode OLED, second light L2 which is emitted from an area between the outer curved surface 6211 and the inner curved surface 6212 is extracted to the front of the display device, and first light L1 and the third light L3 which are emitted from the outer curved surface 6211 and the inner curved surface 6212 may be easily extracted in a lateral direction of the display device. Accordingly, even if the user looks at the display device from the side rather than the front thereof, the user can view the light without color distortion, and thus, overall visibility can be improved.

Meanwhile, as described with reference to FIG. 2, at least a portion of the substrate 501 of the display devices 500 and 600 may have flexibility, and the substrate 501 having flexibility includes a bending area. The bending area may belong to or correspond to any one of the outer areas OA1 and OA2. The curved areas where the convex portions 520 and 620 are disposed may be included as at least a part of the bending area. In other words, in an example, the convex portions 520 and 620 may be disposed in the bending areas.

Meanwhile, convexities of the convex portions 520 and 620 may be designed differently based on a color of light generated through the organic light emitting diode OLED. For example, an organic light emitting diode generating red light may have a convexity in a range of about 1 to 1.5 times a predetermined reference convexity, an organic light emitting diode generating green light may have a convexity in a range of about 2 to 4 times the reference convexity, and an organic light emitting diode generating blue light may have a convexity in a range of about 0.5 to 2 times the reference convexity.

Also, the convex portions 520 and 620 may be manufactured using a halftone mask. For example, the convex portions 520 and 620 having curved surfaces may be manufactured by stacking an organic layer used as a material for convex portions on the insulating layers 510 and 610, performing a photo process on the organic layer through a halftone mask having a transmittance which is adjusted for each area, and then, performing a developing process. To manufacture shapes of the convex portions 520 and 620, halftone masks may be designed to have a transmittance of 0% at positions which correspond to centers of the convex portions 520 and 620 and to have a transmittance of 100% at positions in which heights 523 and 623 of the convex portions 520 and 620 are 0 and which correspond to the connection portions 530 and 630. However, the present disclosure is not limited thereto.

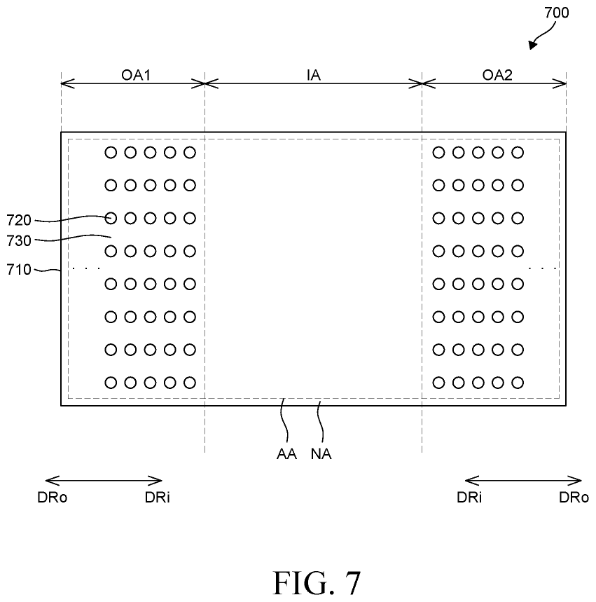

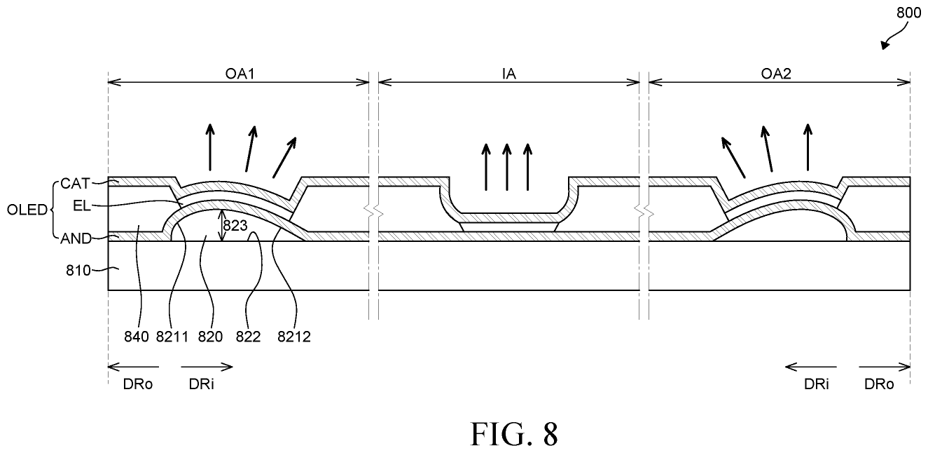

FIG. 7 is a schematic plan view of a display device according to still another exemplary embodiment of the present disclosure. FIG. 8 is a cross-sectional view illustrating a stacked structure of an organic light emitting diode disposed in the display device according to still another exemplary embodiment of the present disclosure.

Referring to FIG. 7, display devices 700 and 800 include an active area AA and a non-active area NA, and an inner area IA and outer areas OA1 and OA2 thereof include the active area AA at least partially. The display devices 700 and 800 may display an image in both the inner area IA and the outer areas OA1 and OA2.

The display devices 700 and 800 include insulating layers 710 and 810 disposed on a substrate. The insulating layers 710 and 810 may be disposed on the inner area IA and the outer areas OA1 and OA2. For example, the insulating layers 710 and 810 may be disposed in an entirety of the active area AA of the inner area IA and in a part or an entirety of the non-active area NA. In addition, the insulating layers 710 and 810 may be disposed in an entirety of the active area AA and in a part or an entirety of the non-active area NA in the outer areas OA1 and OA2.

A plurality of convex portions 720 and 820 may be disposed on the insulating layers 710 and 810. The plurality of convex portions 720 and 820 may be disposed in the outer areas OA1 and OA2 of the display devices 700 and 800. The convex portions 720 and 820 have shapes in which they protrude to form curved surfaces toward fronts of the display devices 700 and 800. Referring to FIG. 7, the convex portions 720 and 820 may be disposed in a shape of dots and may be disposed in the outer areas OA1 and OA2 of the display devices 700 and 800. The respective convex portions 720 and 820 may be disposed to be spaced apart from each other. In addition, as described above with reference to FIG. 4, the convex portions 720 and 820 may be disposed in a shape of lines having long axes in the column direction, and disposed in the outer areas OA1 and OA2 of the display devices 700 and 800. Meanwhile, the convex portions 720 and 820 may not be disposed in the inner area IA.

Meanwhile, the plurality of convex portions 720 and 820 disposed on the insulating layers 710 and 810 may be connected to each other by connection portions 730 surrounding the convex portions 720 and 820, respectively. The connection portions 730 are configured to surround the convex portions 720 and 820, respectively. In addition, the connection portions 730 may be formed of the same material as the convex portions 720 and 820. For example, the connection portions 730 may be formed of polyimide (PI) or polyacrylate (PAC), but are not limited thereto. For example, the connection portions 730 may be formed of a material different from that of the convex portions 720 and 820.

Referring to FIG. 8, the first electrode AND is disposed on the insulating layer 810 and the convex portion 820, and a bank 840 is disposed on the first electrode AND. At least a portion of the bank 840 may be disposed on the first electrode AND that forms a curve by the convex portion 820. The emission layer EL is disposed on the front surface of the first electrode AND to overlap the convex portion 820, and the second electrode CAT is disposed on the emission layer EL and the bank 840.

According to another exemplary embodiment of the present disclosure, the convex portions 720 and 820 may be disposed in a large screen display device. If the large screen display device emits light to the front thereof from the inner area IA and the outer areas OA, OA1 and OA2, the light emitted from the outer areas OA, OA1 and OA2 may be partially distorted and perceived by a user. That is, the user's visibility to the inner area IA and the outer areas OA, OA1 and OA2 may be different. In order to prevent or at least reduce such degradation in visibility, the display devices according to various exemplary embodiments of the present disclosure include the convex portions 720 and 820 in the outer areas OA, OA1 and OA2, and light generated from the organic light emitting diode OLED can be effectively transmitted to the user in front of the display device by the convex portions 720 and 820. In addition, by not including the convex portions 720 and 820 in the inner area IA or designing a height 823 of the convex portions 720 and 820 to be small, the display device can effectively transmit light to the user in front of the display device.

In addition, according to another exemplary embodiment of the present disclosure, the convex portions 720 and 820 may also be disposed in a flexible display device. This is because light distortion may occur in the outer areas OA, OA1 and OA2 even in the case of the flexible display device, similarly to a large screen display device. The flexible display device radiates light in a front direction. However, when the outer areas OA, OA1 and OA2 are formed as a bending area, light may exit in a different direction other than the front direction, as described above with reference to FIG. 2. This may degrade the visibility of a user looking at the flexible display device in a front thereof. To prevent such degradation in visibility, in the display devices according to various exemplary embodiments of the present disclosure, the convex portions 720 and 820 are disposed in the outer areas OA, OA1 and OA2, and light generated from the organic light emitting diode OLED can be effectively transmitted to a user in front of the display device by the convex portions 720 and 820. In addition, by not including the convex portions 720 and 820 in the inner area IA or designing the height 823 of the convex portions 720 and 820 to be small, the display device can effectively transmit light to the user in front of the display device.

Meanwhile, according to various exemplary embodiments of the present disclosure, the shapes of the convex portions 720 and 820 may be differently designed according to positions so that a light path is formed toward the front of the display device. Hereinafter, with reference to FIG. 8, the convex portion differently designed according to a position will be described.

Referring to FIG. 8, the convex portion 820 includes an outer curved surface 8211, an inner curved surface 8212, and a bottom surface 822, and the outer curved surface 8211 and the inner curved surface 8212 are divided based on a peak point where the height 823 is greatest. The outer curved surface 8211 is located in an outward direction DRo, and the inner curved surface 8212 is located in an inward direction DRi.

The outer areas include a first outer area OA1 and a second outer area OA2, and the inner area IA may be positioned between the first outer area OA1 and the second outer area OA2. In an example, the first outer area OA1 and the second outer area OA2 may be positioned symmetrically with respect to each other. Also, the first outer area OA1 and the second outer area OA2 may be formed symmetrically with respect to each other.

The convex portion 820 disposed in the first outer area OA1 may be formed in a shape symmetrical to the convex portion 820 disposed in the second outer area OA2 with respect to the inner area IA. Hereinafter, the convex portion 820 disposed in the first outer area OA1 will be mainly described, and it may be understood that the convex portion 820 disposed in the second outer area OA2 is symmetrical to the convex portion 820 disposed in the first outer area OA1 with respect to the inner area IA.

The convex portion 820 has the height 823 which is greatest at the peak point. A peak point of the convex portion 820 is located in the outward direction Dro from a center thereof, and thus the inner curved surface 8212 is formed in a wider area than the outer curved surface 8211. Also, the inner curved surface 8212 may have a larger radius of curvature than the outer curved surface 8211.

The peak point of the convex portion 820 may be located more outward from the center of the convex portion 820 in the outward direction Dro. As the peak point of the convex portion 820 is disposed in the outward direction Dro, an area corresponding to the inner curved surface 8212 of the convex portion 820 gets wider than an area corresponding to the outer curved surface 8211 of the convex portion 820. In addition, as the peak point of the convex portion 820 is disposed in the outward direction Dro, the inner curved surface 8212 of the convex portion 820 may have a larger radius of curvature than the outer curved surface 8211. In addition, in an example, the height 823 of the convex portion 820 may increase as the convex portion 820 is disposed in the outward direction Dro, and the height 823 of the convex portion 820 may decrease as the convex portion 820 is disposed in the inward direction Dri.

Although not limited to, the convex portion 820 may not be disposed in the inner area IA of the display device. The organic light emitting diode OLED of the inner area IA is formed flat, thereby enabling light to be emitted in the front direction without diffusing the light in a dome shape.

As described above, by moving the peak points of the convex portions 820 disposed in the first outer area OA1 and the second outer area OA2 in the outward directions Dro, the organic light emitting diodes OLED disposed on the convex portions 820 of the first outer area OA1 and the second outer area OA2 radiate light relatively in the inward directions Dri. Accordingly, light distortion in the outer areas may be reduced in the case of a large area display device, and light distortion in the outer areas may be reduced even in the case of a flexible display device.

Meanwhile, a stacked structure illustrated in FIG. 8 may be substantially equally applied to the display devices according to various exemplary embodiments described above with reference to FIGS. 3 and 4. In other words, peak points of the convex portions illustrated in FIGS. 3 and 4 may vary depending on positions at which the convex portions are disposed. More specifically, the peak point may be located further outward from the center of the convex portion as it is disposed in the outward direction.

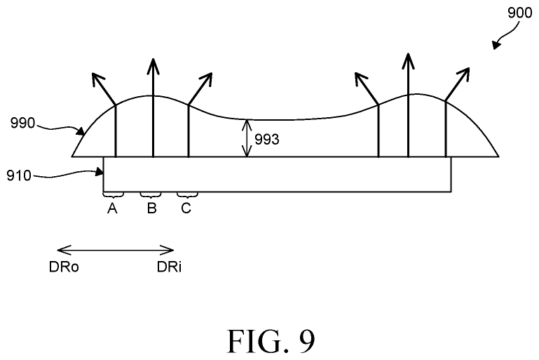

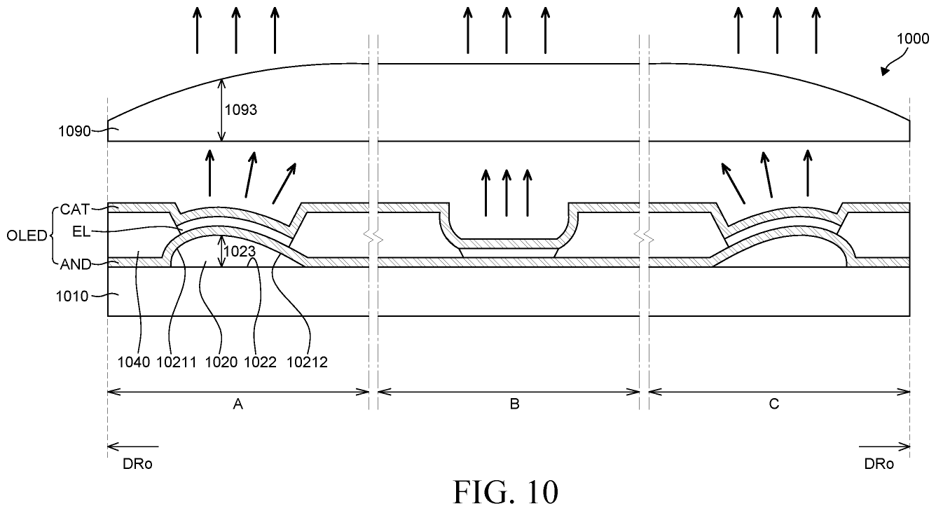

FIG. 9 is a schematic cross-sectional view of a display device including a protective layer according to still another exemplary embodiment of the present disclosure. FIG. 10 is a cross-sectional view illustrating a stacked structure of an organic light emitting diode disposed in the display device of FIG. 9. In particular, FIG. 10 shows part A, part B, and part C of FIG. 9, respectively.

Referring to FIGS. 9 and 10, display devices 900 and 1000 include a display panel 910 and protective layers 990 and 1090. Thicknesses 993 and 1093 of the respective protective layers 990 and 1090 disposed on the display panel 910 may be different according to areas. For example, the respective thicknesses 993 and 1093 of the protective layers 990 and 1090 may form curved surfaces on surfaces of the display panel and may be designed differently according to areas.

As described above, since the protective layers 990 and 1090 have uneven surfaces, light paths of light output from the display panel 910 may be scattered in directions which are not intended by the designer of the display panel 910. Accordingly, a convex portion 1020 provided inside the display panel 910 and an organic light emitting diode OLED disposed on the convex portion 1020 may be formed such that light paths are uniformly aligned toward the front. Here, the first electrode AND, the second electrode CAT, and the emission layer EL constituting the organic light emitting diode OLED are configured to be substantially identical to those described with reference to FIGS. 2 to 8. That is, the first electrode AND is disposed on an insulating layer 1010 and the convex portion 1020, and a bank 1040 may be disposed on the first electrode AND being curved by the convex portion 1020.

In part A of FIG. 10, the protective layer 1090 refracts incident light outward. In part B of FIG. 10, the protective layer 1090 vertically transmits incident light. In part C of FIG. 10, the protective layer 1090 refracts incident light inward.

The convex portions 1020 in parts A, B, and C of FIG. 10 have different shapes. Similar to those of the various exemplary embodiments described above, the convex portion 1020 includes an outer curved surface 10211, an inner curved surface 10212, and a bottom surface 1022, and the outer curved surface 10211 and the inner curved surface 10212 are divided based on a peak point where a height 1023 is greatest. Meanwhile, as illustrated with reference to FIG. 9, parts A, B, and C are understood as parts located on one side of a center of the display device.

Referring to FIG. 10, part A refers to a part of the display device in which light is refracted outward by the protective layer 1090. Part A is an area in which a thickness of the protective layer increases in an inward direction, and a peak point of the convex portion in part A may be located away from a center of the convex portion in an outward direction. Specifically, in part A, the peak point of the convex portion 1020 may be located further outward from the center. Accordingly, a radius of curvature of the inner curved surface 10212 becomes greater than a radius of curvature of the outer curved surface 10211, and light emitted from the organic light emitting diode disposed on the convex portion 1020 is directed relatively in the inward direction. The light emitted in the inward direction may pass through the protective layer 1090 and proceed toward in a front direction.

Part B of FIG. 10 refers to a part of the display device in which light passes through the protective layer 1090 as it is along a direction in which light is incident, without being refracted inward or outward by the protective layer 1090. Part B of FIG. 10 is an area in which the thickness of the protective layer is uniform, and no convex portion is formed in the part B, and the convex portion may be disposed in an area in which the thickness of the protective layer varies in an inward or outward direction, such as in part A described above or part C of FIG. 10 which will be described later. Specifically, in part B of FIG. 10, since there is no need to adjust a light path of light emitted from the organic light emitting diode by changing a shape of the organic light emitting diode, the organic light emitting diode can be evenly disposed on the insulating layer.

Part C of FIG. 10 refers to a part of the display device in which light is refracted inward by the protective layer 1090. Part C of FIG. 10 is an area in which the thickness of the protective layer increases in the outward direction, and a peak point of the convex portion in part C may be located away from the center of the convex portion in the inward direction. Specifically, in part C of FIG. 10, the peak point of the convex portion 1020 may be located more inward from the center of the convex portion. Accordingly, the radius of curvature of the outer curved surface 10211 becomes larger than the radius of curvature of the inner curved surface 10212, and light emitted from the organic light emitting diode disposed on the convex portion 1020 is directed relatively in the outward direction. The light emitted in the outward direction may pass through the protective layer 1090 and proceed in the front direction.

The exemplary embodiments of the present disclosure can also be described as follows:

According to an aspect of the present disclosure, there is provided an organic light emitting display device. The organic light emitting display device comprises an insulating layer disposed on a substrate, an organic light emitting diode disposed on the insulating layer and including a first electrode, an emission layer, and a second electrode, wherein the insulating layer includes a convex portion disposed in a curved area protruding forward, wherein the emission layer is disposed in an emission area, and the emission area is included in the curved area as at least a part of the curve area, wherein the organic light emitting diode is disposed on the convex portion to have a shape corresponding to a surface shape of the convex portion in the emission area.

The emission area may be defined by a bank disposed on the insulating layer and the first electrode, wherein at least a portion of the bank is disposed on the curve area, the emission area may be at least included in a portion of the curve area, and the emission layer may have the shape corresponding to the surface shape of the convex portion overall.

The convex portion may be formed of the same material as the insulating layer.

The organic light emitting display device may include a plurality of outer areas and an inner area positioned between the outer areas, and the convex portion is disposed in the outer areas.

The convex portion may be disposed only in the outer areas.

A portion of the insulating layer, that is disposed in the inner area may be disposed in a flat shape, and a portion of the organic light emitting diode, that is disposed in the inner area may be disposed flat along a surface shape of the insulating layer, and a portion of the organic light emitting diode, that is disposed in the outer area may be disposed in a shape protruding forward along the surface shape of the convex portion.

The outer areas may include a first outer area positioned on one side of the inner area and a second outer area positioned on the other side of the inner area, based on the inner area, wherein the convex portion disposed in the first outer area may be formed symmetrically with the convex portion disposed in the second outer area with respect to the inner area.

The convex portion may include an outer curved surface and an inner curved surface, wherein the outer curved surface and the inner curved surface may be divided based on a peak point at which a height of the convex portion is greatest, wherein the outer curved surface may be positioned in an outward direction of the substrate, compared to the inner curved surface.

The peak point of the convex portion may be further away from a center of the convex portion in the outward direction as the convex portion is disposed in the outward direction.

The inner curved surface may have a larger radius of curvature than the outer curved surface.

A radius of curvature of the outer curved surface may decrease as the convex portion is disposed in the outward direction.

A height of the convex portion may increase as the convex portion is disposed in the outward direction.

A convexity of the convex portion may be differently designed according to a color of light generated through the organic light emitting diode.

The substrate may include a bending area, and the curved area may be at least included in a part of the bending area.

The organic light emitting display may further comprise a protective layer disposed on the organic light emitting diode, wherein the protective layer has different thicknesses according to areas.

In an area in which the thickness of the protective layer increases in an inward direction, the peak point of the convex portion may be located away from a center of the convex portion in an outward direction.

In an area in which the thickness of the protective layer increases in an outward direction, the peak point of the convex portion may be located away from a center of the convex portion in an inward direction.

The convex portion may be not formed in an area in which the thickness of the protective layer is uniform, and the convex portion may be disposed in an area in which the thickness of the protective layer varies in an inward direction or an outward direction.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. An organic light emitting display device, comprising:
an insulating layer on a substrate; and
an organic light emitting diode on the insulating layer, the organic light emitting diode including a first electrode, an emission layer on the first electrode, and a second electrode on the emission layer,
wherein the insulating layer includes a convex portion in a curved area protruding towards a direction of the organic light emitting diode,
wherein the emission layer is in an emission area, and the emission area is included in the curved area as at least a part of the curved area,
wherein the organic light emitting diode is on the convex portion and has a shape corresponding to a surface shape of the convex portion in the emission area.

2. The organic light emitting display device of claim 1, wherein the emission area is defined by a bank disposed on the insulating layer and the first electrode,
wherein at least a portion of the bank is on the curved area, and the emission layer has a shape corresponding to the surface shape of the convex portion.

3. The organic light emitting display device of claim 1, wherein the convex portion comprises a same material as the insulating layer.

4. The organic light emitting display device of claim 1, wherein the organic light emitting display device includes a plurality of outer areas and an inner area between the plurality of outer areas, and the convex portion is in the plurality of outer areas but not the inner area.

5. The organic light emitting display device of claim 1, wherein the organic light emitting display device includes a plurality of outer areas and an inner area between the plurality of outer areas, and the convex portion is in the plurality of outer areas and the inner area.

6. The organic light emitting display device of claim 4, wherein a portion of the insulating layer, that is in the inner area comprises a flat shape, and a portion of the organic light emitting diode, that is in the inner area is flat along a surface shape of the insulating layer, and a portion of the organic light emitting diode, that is in a outer area from the plurality of outer areas is in a shape bending along the surface shape of the convex portion.

7. The organic light emitting display device of claim 4, wherein the plurality of outer areas include a first outer area on one side of the inner area and a second outer area on another side of the inner area,
wherein the convex portion in the first outer area is symmetrical with the convex portion in the second outer area with respect to the inner area.

8. The organic light emitting display device of claim 1, wherein the convex portion includes an outer curved surface and an inner curved surface,
wherein the outer curved surface and the inner curved surface are divided based on a peak point at which a height of the convex portion is greatest,
wherein the outer curved surface is positioned in an outward direction of the substrate, compared to the inner curved surface.

9. The organic light emitting display device of claim 8, wherein the peak point of the convex portion is further away from a center of the convex portion in the outward direction as the convex portion is disposed in the outward direction.

10. The organic light emitting display device of claim 8, wherein the inner curved surface has a larger radius of curvature than a radius of curvature of the outer curved surface.

11. The organic light emitting display device of claim 8, wherein a radius of curvature of the outer curved surface decreases as the convex portion is disposed in the outward direction.

12. The organic light emitting display device of claim 8, wherein a height of the convex portion increases as the convex portion is disposed in the outward direction.

13. The organic light emitting display device of claim 1, wherein a convexity of the convex portion is different according to a color of light generated through the organic light emitting diode.

14. The organic light emitting display device of claim 1, wherein the substrate includes a bending area, and the curved area is at least included in a part of the bending area.

15. The organic light emitting display device of claim 1, further comprising:
a protective layer on the organic light emitting diode,
wherein the protective layer has different thicknesses according to areas.

16. The organic light emitting display device of claim 15, wherein in an area in which a thickness of the protective layer increases in an inward direction, and a peak point of the convex portion is located away from a center of the convex portion in an outward direction.

17. The organic light emitting display device of claim 15, wherein in an area in which a thickness of the protective layer increases in an outward direction, and a peak point of the convex portion is located away from a center of the convex portion in an inward direction.

18. The organic light emitting display device of claim 15, wherein the convex portion is not in an area in which a thickness of the protective layer is uniform, and the convex portion is in an area in which the thickness of the protective layer varies in an inward direction or an outward direction.

19. The organic light emitting display device of claim 1, wherein the convex portion has a shape of dots or shape of lines.

20. The organic light emitting display device of claim 1, wherein convex portions are connected to each other by connection portions surrounding the convex portions respectively.

21. The organic light emitting display device of claim 20, wherein the connection portions are integrally formed with the convex portions.

22. An organic light emitting display device, comprising:
an insulating layer on a substrate; and
an organic light emitting diode on the insulating layer, the organic light emitting diode including a first electrode, an emission layer on the first electrode, and a second electrode on the emission layer,
wherein the insulating layer includes a convex portion protruding towards a direction of the organic light emitting diode, and a part of the first electrode covering the convex portion has a shape corresponding to the convex portion.

23. The organic light emitting display device of claim 22, further comprising:
a bank on the insulating layer, the bank extending to one side or two sides of the part of the first electrode, and the emission layer is at a position of the part of the first electrode exposed by the bank.

24. The organic light emitting display device of claim 22, wherein an area of the insulating layer with the convex portion is a curved area, and an area of the insulating layer with the emission layer is an emission area, and the curved area includes the emission area.
